(19) United States
(12) Patent Application Publication
(10) Pub. No.: US 2008/0048528 A1
(43) Pub. Date: Feb. 28, 2008

(54) Piezoelectric Actuator

(76) Inventor: Ulrich Schoor, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 11/628,613

(22) PCT Filed: Apr. 25, 2005
(86) PCT No.: PCT/EP05/51832

§ 371 Date: Dec. 6, 2006

(30) Foreign Application Priority Data
Jun. 30, 2004 (DE) 102004031596.5

(51) Int. Cl. H01L 41/083

(52) U.S. Cl. 310/365

(57) ABSTRACT

A piezoelectric actuator for example for a mechanical component control, comprises a plurality of piezoelectric layers of at least one piezoelectrically active region and internal electrodes which are inserted between said layers and are alternately supplied with a different polarity electric voltage. The piezoelectric actuator including the head and/or base area thereof is actively mounted, and the internal electrodes are entirely buried into the head and/or base area except a minimum contact area for respective external contacts.

### PRIOR ART

The invention relates to a piezoelectric actuator, for instance for actuating a mechanical component, as defined by the generic characteristics of the main claim.

It is known, for instance from German Patent Disclosure DE 199 28 189 A1, that by using the so-called piezoelectric effect, a piezoelectric element for controlling the needle stroke of a valve or the like can be constructed from a material having a suitable crystalline structure. Upon application of an external electrical voltage, a mechanical reaction of the piezoelectric element occurs, and this reaction, depending on the crystalline structure and on the regions to which the electrical voltage is applied, represents a pressure or tension in a predeterminable direction.

Because of the extremely fast and precisely regulatable stroke effect, such piezoelectric actuators can be provided for constructing final control elements, for instance for driving switching valves in fuel injection systems in motor vehicles. The voltage- or charge-controlled deflection of the piezoelectric actuator is utilized in that case for positioning a control valve, which in turn regulates the stroke of a nozzle needle.

Since the required electrical field intensities for actuating the piezoelectric actuator are in the range of several kV/mm, and since as a rule, moderate electrical voltages for triggering are desired, the construction of this piezoelectric actuator is done here in a plurality of layers of metallized piezoelectric ceramics, stacked one above the other, to make a so-called multilayer actuator. For this purpose, between the various layers, there are inner electrodes which are applied for instance by a printing process, and there are also outer electrodes, by way of which the electrical voltage is applied. A typical method for producing such layers is the foil casting technique. The various layers are metallized and stacked one above the other for producing the inner electrodes, and then the piezoelectric effect develops between two layers with inner electrodes of different polarity.

Typically, such piezoelectric actuators are provided with inner electrodes which over the full broad side have a recessed or in other words buried inner electrode on one of four sides. On all the other sides, the inner electrode extends outward as far as the edge of the ceramic. Piezoelectric actuators are also known whose inner electrodes are recessed on all sides, with the exception of the bonding strip on the outside of the piezoelectric actuator. These arrangements can have various bonding zones, for instance over a surface or at corners.

As a rule, for installation in corresponding actuator arrangements, these known piezoelectric actuators have passive head and foot parts, which are not provided with inner electrodes. In other words, special guidance or fitting zones must be provided, and a covering or insulation layer is necessary, which could easily become damaged.

### ADVANTAGES OF THE INVENTION

The piezoelectric actuator known from the prior art is provided with a multilayer construction comprising piezoelectric layers that each comprise a passive region with or without inner electrodes and a piezoelectrically active region with bonded inner electrodes located between the layers. In the active region, the piezoelectric actuator has bonding of the inner electrodes that changes from one layer to the next, for subjection to an electrical voltage. In the invention, conversely, the piezoelectric actuator, including a head and/or foot region, is advantageously constructed actively with bonded inner electrodes, but the inner electrodes in the head and/or foot region are fully buried, except for a minimal contact zone for the respective external bond, unlike the central active region.

For many applications, piezoelectric actuators whose active region extends from the head to the foot over the entire piezoelectric actuator are advantageous, so that guidance or fitting zones in the foot region and optionally in the head region are omitted. Active regions with inner electrodes conventionally extended to the outside, however, must intrinsically be covered in an electrically insulated manner, to prevent surface conduction or creepage. As a rule, covering compositions are used, such as silicone resins or silicone elastomers or other insulating materials, insulating paints, or insulation layers, which are highly vulnerable to mechanical damage in production and further processing.

The embodiment according to the invention of a fully active piezoelectric actuator does not require any covering with an insulation layer in the fitting or joining region at the head or foot. Here an advantageous combination of different burials of the inner electrodes in the layered construction of the piezoelectric actuator is proposed, in which the only partly buried inner electrodes make an unhindered expansion possible in the central, free region, while in the joining region at the head and/or foot, additional layers with virtually fully-buried inner electrodes are activatable.

The slight sacrifices that occur here from the slightly lesser expansion capacity of the virtually fully-buried inner electrode design in the head and/or foot region are easily tolerated. The remaining contact zone in each case makes up a relatively small proportion of the total width of the external bond.

### DRAWING

One exemplary embodiment of the piezoelectric actuator of the invention will be described in conjunction with the drawing figures. Shown are:

FIG. 1, a schematic view of a piezoelectric actuator with a head and foot region in a complete active construction;

FIG. 2, a detail of a layered construction in the central, free region of the piezoelectric actuator, with partly-buried inner electrodes; and

FIG. 3, a detail of a layered construction in the head or foot region of the piezoelectric actuator, with virtually fully-buried inner electrodes.

### DESCRIPTION OF THE EXEMPLARY EMBODIMENT

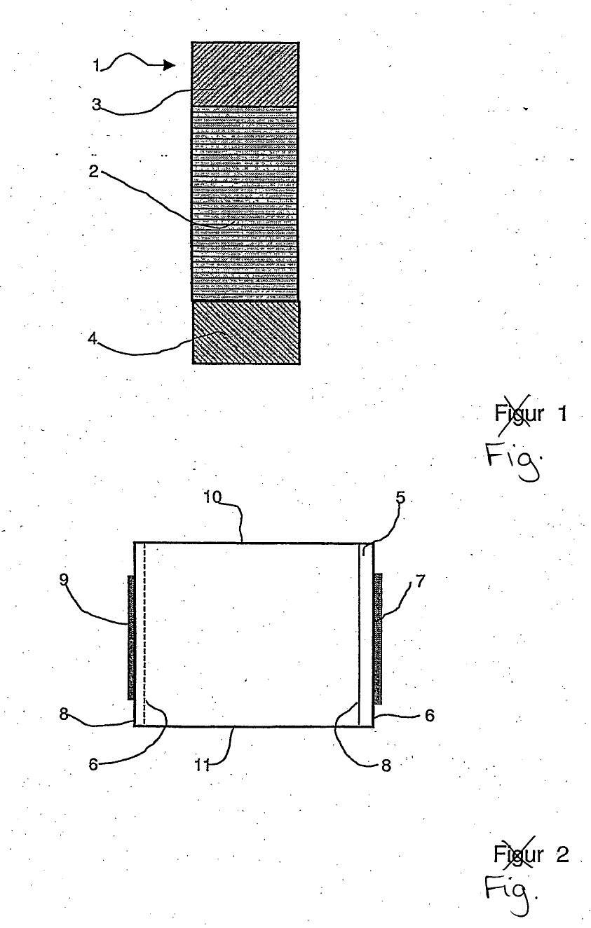

In FIG. 1, a piezoelectric actuator 1 is schematically shown, constructed in a manner known per se from piezoelectric layers of a ceramic material, such as so-called green sheets, with a suitable crystalline structure, so that by utilizing the so-called piezoelectric effect upon application of an external electrical direct voltage to inner electrodes via externally bonded electrodes, a mechanical reaction of the piezoelectric actuator 1 ensues.

The piezoelectric actuator 1 is constructed entirely of such piezoelectrically active regions, specifically a central, free region 2 and a head region 3 as well as a foot region 4; the head and/or foot region 3, 4 serves the purpose in particular of mechanically retaining the piezoelectric actuator 1.

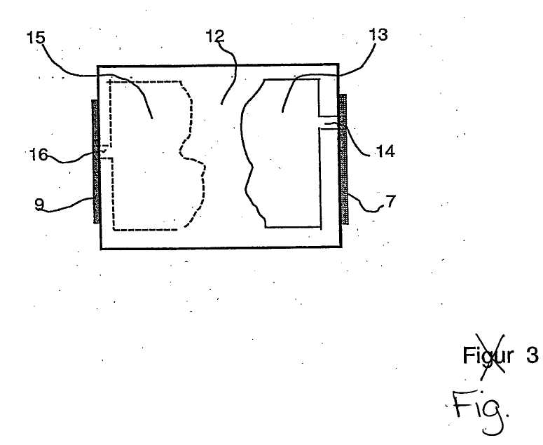

In detail, FIG. 2 shows the construction of a piezoelectric layer in the central region 2 of FIG. 1, with a ceramic layer 5 and an inner electrode 6; this electrode is covered on the right-hand edge by the ceramic layer 5 and is supplied with one pole of a voltage via a bond 7 mounted on the piezoelectric actuator 1 on the outside. The inner electrode 6 is covered on the left-hand edge of the layered construction not only by the ceramic layer 5 but also by the inner electrode 8 located above it, which is supplied with the other pole of the voltage via an external bond 9. The non-visible edge of the inner electrode 6 is shown in dashed lines in the left-hand portion of the layered construction.

It can thus be seen from FIG. 2 that the non-bonded edge of the inner electrode 6 in the left-hand part and the non-bonded edge of the inner electrode 8 in the right-hand part are each covered and thus partly buried. For external covering, an insulation layer, for instance of silicone resin or silicone elastomer, is mounted on the sides 10 and 11 of the piezoelectric actuator 1. The construction of the active region 2 thus comprises the previously usual construction with inner electrodes, which are recessed on only one side and thus enable the maximum possible expansion. The construction of the piezoelectric actuator 1 may be done rectangularly, as shown, or with a contour that is beveled at the corners.

From FIG. 3, the construction of a piezoelectric layer with a ceramic layer 12 in the head or foot region 3 or 4 of FIG. 1 can be seen. Here, an inner electrode 13 is connected to the bond 7, mounted on the outside of the piezoelectric actuator 1, via a relatively small contact zone 14. For the sake of greater clarity, the left-hand part of the inner electrode 13, which here has no further external bond, is cut off. The inner electrode 15 located beneath it in the left-hand part of the piezoelectric layer can also be seen, in dashed lines and also cut off, and it is likewise connected to the bond 9, mounted on the outside of the piezoelectric actuator 1, via a relatively small contact zone 16. The location of the contact zones 14, 16 can be central on the side of the piezoelectric actuator 1, or on both sides, or offset to only one side from the middle.

It can thus be seen from FIG. 3 that the two inner electrodes 13 and 15 shown as examples are virtually completely buried in the construction of the piezoelectric layer, since except for the relatively small contact zones 14 and 16, no inner electrode surfaces are extended to the outside as far as the ceramic surface of the piezoelectric actuator 1, and thus all the way around, no inner electrodes protrude to the outside. It is thus attained according to the invention that in the foot and/or head region 3, 4, the side faces of the piezoelectric actuator 1 need not be covered, and thus no damage to the insulation layer can occur.

1-6. (canceled)

7. A piezoelectric actuator, having
a multilayer construction of piezoelectric layers comprising at least one piezoelectrically active region with inner electrodes disposed between the piezoelectric layers, which inner electrodes can be subjected in alternation to an electrical voltage of different polarity, and one polarity each on one side and/or corner of the piezoelectric actuator is bonded on the outside along its length, and the unbonded outer edges, located in alternation between them, of the respective other polarity are buried on one side and/or corner each in the layered construction, and having
a head and/or foot region on the piezoelectric actuator, each region having a construction differing from the piezoelectric actuator, the improvement wherein
the piezoelectric actuator including its head and/or foot region is actively constructed, and the inner electrodes are fully buried in the head and/or foot region except for a minimal contact zone with the respective external bond.

8. The piezoelectric actuator as defined by claim 7, wherein
each contact zone makes up only a slight proportion of the total width of the external bond.

9. The piezoelectric actuator as defined by claim 8, wherein
the contact zones include a region of from about 20% to 50% of the width of the piezoelectric actuator.

10. The piezoelectric actuator as defined by claim 9, wherein
the contact zones are located centrally or laterally offset from the center of the piezoelectric actuator.

11. The piezoelectric actuator as defined by claim 7, wherein
the active head and/or foot region unlike the central active region has no insulation layer on the outer faces that are not provided with the external bond.

12. The piezoelectric actuator as defined by claim 8, wherein
the active head and/or foot region unlike the central active region has no insulation layer on the outer faces that are not provided with the external bond.

13. The piezoelectric actuator as defined by claim 9, wherein
the active head and/or foot region unlike the central active region has no insulation layer on the outer faces that are not provided with the external bond.

14. The piezoelectric actuator as defined by claim 10, wherein
the active head and/or foot region unlike the central active region has no insulation layer on the outer faces that are not provided with the external bond.

15. The piezoelectric actuator as defined by claim 11, wherein
the insulation layer is a silicone resin, a silicone elastomer, a paint, or other insulation layer.

16. The piezoelectric actuator as defined by claim 12, wherein
the insulation layer is a silicone resin, a silicone elastomer, a paint, or other insulation layer.

17. The piezoelectric actuator as defined by claim 13, wherein
the insulation layer is a silicone resin, a silicone elastomer, a paint, or other insulation layer.

18. The piezoelectric actuator as defined by claim 14, wherein
the insulation layer is a silicone resin, a silicone elastomer, a paint, or other insulation layer.
